(19) United States
(12) Patent Application Publication
(10) Pub. No.: US 2026/0255577 A1
(43) Pub. Date: Aug. 27, 2026

(54) SEMICONDUCTOR DEVICE WITH INTERFACE LAYER AND METHOD FOR FABRICATING THE SAME

(71) Applicant: NANYA TECHNOLOGY CORPORATION, NEW TAIPEI CITY (TW)

(72) Inventors: CHUN-LIN LU, NEW TAIPEI CITY (TW); JYUN-HUA YANG, NEW TAIPEI CITY (TW)

(21) Appl. No.: 19/079,778

(22) Filed: Mar. 14, 2025

Related U.S. Application Data
(63) Continuation of application No. 19/061,001, filed on Feb. 24, 2025.

(51) Int. Cl. H10B 12/00; H10D 1/68; H10D 62/10

(52) U.S. Cl. CPC H10B 12/315; H10B 12/318; H10D 1/696; H10D 1/716; H10D 62/102; H10B 12/0335

(57) ABSTRACT

The present application discloses a semiconductor device and a method for fabricating the semiconductor device. The semiconductor device includes a substrate; a capacitor structure including a bottom electrode layer positioned above the substrate, a treated interface layer positioned on the bottom electrode layer, a capacitor bottom dielectric layer positioned on the treated interface layer, a capacitor top dielectric layer positioned on the capacitor bottom dielectric layer, and a top electrode layer positioned on the capacitor top dielectric layer. The treated interface layer includes titanium oxide nitride.

### CROSS-REFERENCE TO RELATED APPLICATION

This application is a continuation application of U.S. Non-Provisional application Ser. No. 19/061,001 filed Feb. 24, 2025, which is incorporated herein by reference in its entirety.

### TECHNICAL FIELD

The present disclosure relates to a semiconductor device and a method for fabricating the semiconductor device, and more particularly, to a semiconductor device with an interface layer and a method for fabricating the semiconductor device with the interface layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a capacitor structure including a bottom electrode layer positioned above the substrate, a treated interface layer positioned on the bottom electrode layer, a capacitor bottom dielectric layer positioned on the treated interface layer, a capacitor top dielectric layer positioned on the capacitor bottom dielectric layer, and a top electrode layer positioned on the capacitor top dielectric layer. The treated interface layer includes titanium oxide nitride.

Another aspect of the present disclosure provides a semiconductor device including a substrate; a capacitor structure including a bottom electrode layer positioned above the substrate, an interface layer positioned on the bottom electrode layer, a capacitor bottom dielectric layer positioned on the interface layer, a capacitor top dielectric layer positioned on the capacitor bottom dielectric layer, and a top electrode layer positioned on the capacitor top dielectric layer. The interface layer includes titanium oxide.

Another aspect of the present disclosure provides a method for fabricating a semiconductor device including providing a substrate; forming a top inter-dielectric layer above the substrate; forming an opening penetrating the top inter-dielectric layer; forming a bottom electrode layer within the opening; performing an oxygen treatment to form an interface layer on the bottom electrode layer; performing a nitrogen treatment to turn the interface layer into a treated interface layer; forming a capacitor bottom dielectric layer on the treated interface layer; forming a capacitor top dielectric layer on the capacitor bottom dielectric layer; and forming a top electrode layer on the capacitor top dielectric layer. The treated interface layer includes titanium oxide nitride. The bottom electrode layer, the treated interface layer, the capacitor bottom dielectric layer, the capacitor top dielectric layer, and the top electrode layer configure a capacitor structure.

Due to the design of the semiconductor device of the present disclosure, the leakage of the capacitor structures may be reduced by using the interface layer formed through oxygen treatment. Additionally, the treated interface layer, formed through nitrogen treatment and composed of titanium oxide nitride, can minimize impurities in the bottom electrode layer. These improvements collectively enhance the performance and reliability of the semiconductor device. Furthermore, experimental results further demonstrate that combining the treated interface layer, which includes titanium oxide nitride, with the capacitor bottom dielectric layer, composed solely of hafnium oxide, effectively reduces leakage in the capacitor structures without compromising their capacitance. This combination provides a balanced solution for improving both the electrical and functional properties of the capacitor structures.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 12 illustrate, in schematic cross-sectional view diagrams, a flow for fabricating the semiconductor device in accordance with one embodiment of the present disclosure; and

FIG. 13 illustrates, in a schematic cross-sectional view diagram, a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

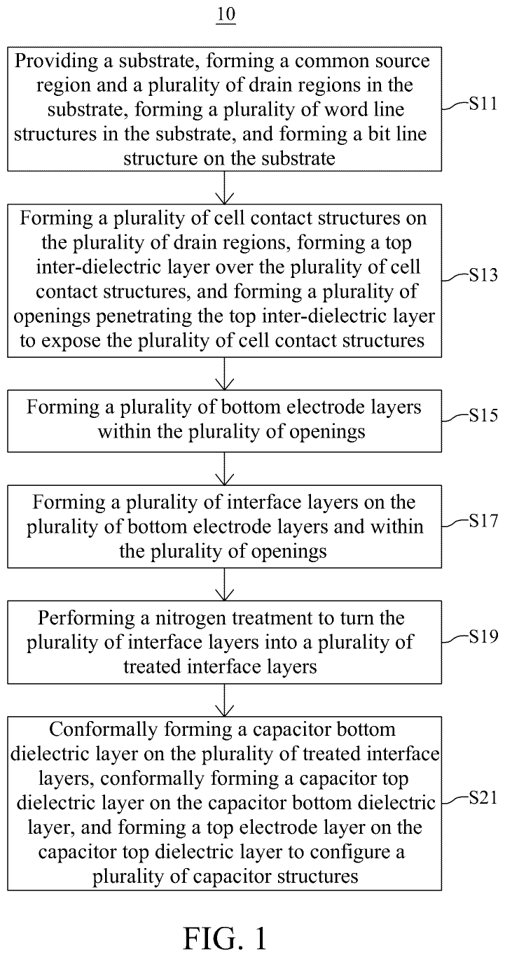

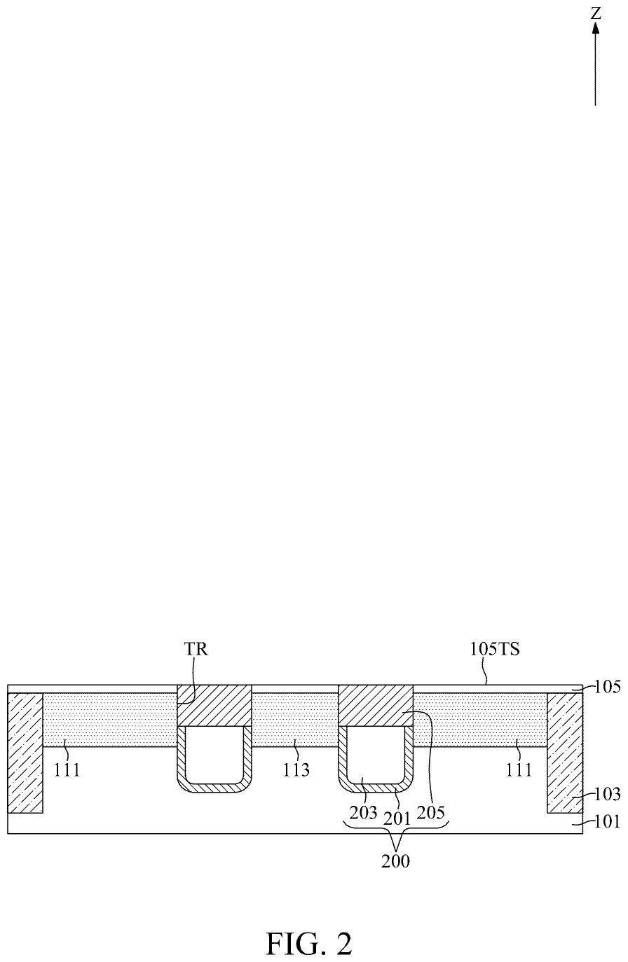

FIG. 1 illustrates, in a flowchart diagram form, a method 10 for fabricating a semiconductor device 1A in accordance with one embodiment of the present disclosure. FIGS. 2 to 12 illustrate, in schematic cross-sectional view diagrams, a flow for fabricating the semiconductor device 1A in accordance with one embodiment of the present disclosure.

With reference to FIGS. 1 to 4, at step S11, a substrate 101 may be provided, a common source region 113 and a plurality of drain regions 111 may be formed in the substrate 101, a plurality of word line structures 200 may be formed in the substrate 101, and a bit line structure 300 may be formed on the substrate 101.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm. The insulator layer may eliminate leakage current between adjacent elements in the substrate 101 and reduce parasitic capacitance associated with source/drains.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIG. 2, the isolation layer 103 may be formed in the substrate 101. A series of deposition processes may be performed to deposit a pad oxide layer (not shown) and a pad nitride layer (not shown) on the substrate 101. A photolithography process and a subsequent etching process, such as an anisotropic dry etching process, may be performed to form trenches penetrating through the pad oxide layer, the pad nitride layer, and extending to the substrate 101. An insulating material may be deposited into the trenches and a planarization process, such as chemical mechanical polishing, may be subsequently performed until the top surface of the substrate 101 is exposed to remove excess filling material, provide a substantially flat surface for subsequent processing steps, and concurrently form the isolation layer 103. The insulating material may be, for example, silicon oxide or other applicable insulating materials. The isolation layer 103 may define the active area (not annotated) in the substrate 101.

It should be noted that, in the description of the present disclosure, a surface of an element (or a feature) located at the highest vertical level along the Z direction (or axis) is referred to as a top surface of the element (or the feature). A surface of an element (or a feature) located at the lowest vertical level along the Z direction is referred to as a bottom surface of the element (or the feature).

With reference to FIG. 2, a bottom dielectric layer 105 may be formed on the substrate 101 and the isolation layer 103. In some embodiments, the bottom dielectric layer 105 may be formed of a material having etching selectivity to the substrate 101 and the isolation layer 103. In some embodiments, the bottom dielectric layer 105 may be formed of, for example, silicon nitride, boron nitride, silicon boron nitride, phosphorus boron nitride, boron carbon silicon nitride, or a combination thereof. In some embodiments, the bottom dielectric layer 105 may be formed of, for example, silicon nitride. In some embodiments, the bottom dielectric layer 105 may be formed by, for example, chemical vapor deposition, plasma-enhanced chemical vapor deposition, or other applicable deposition processes.

With reference to FIG. 2, an impurity region (not annotated) may be formed in the active area. In some embodiments, the impurity region may be formed by an implantation process. That is, the impurity region may be turned from a portion of the active area. The dopants of the implantation process may include p-type impurities (dopants) or n-type impurities (dopants). The p-type impurities may be added to an intrinsic semiconductor to create deficiencies of valence electrons. In a silicon-containing substrate, examples of p-type dopants, i.e., impurities include but are not limited to boron, aluminum, gallium, and indium. The n-type impurities may be added to an intrinsic semiconductor to contribute free electrons to the intrinsic semiconductor. In a silicon-containing substrate, examples of n-type dopants, i.e., impurities, include but are not limited to antimony, arsenic, and phosphorus. In some embodiments, the dopant concentration of the plurality of impurity regions 105 may be between about 1 E19 atoms/cm\hat{ }3 and about 1 E21 atoms/cm\hat{ }3. After the implantation process, the plurality of impurity regions 105 may have an electrical type such as n-type or p-type.

With reference to FIG. 2, a plurality of word line trenches TR may be formed in the substrate 101 to define the position of the plurality of word line structures 200. The plurality of word line trenches TR may be formed by a photolithography process and a following etching process. The plurality of word line trenches TR may penetrate the bottom dielectric layer 105 and extend into the substrate 101. In some embodiments, the impurity region may be intersected with two word line trenches TR. The plurality of word line trenches TR may divide the impurity region into the two drain regions 111 and the common source region 113. The common source region 113 may be formed between the two word line trenches TR and the plurality of drain regions 111 may be formed respectively and correspondingly between the isolation layer 103 and the two word line trenches TR.

With reference to FIG. 2, the plurality of word line structures 200 (e.g., two word line structures 200) may be formed in the plurality of word line trenches TR, respectively and correspondingly. For brevity, clarity, and convenience of description, only one word line structure 200 is described. The word line structure 200 may include a word line dielectric layer 201, a word line conductive layer 203, and a word line capping layer 205.

With reference to FIG. 2, the word line dielectric layer 201 may be conformally formed on the inner surface of the word line trench TR. The word line dielectric layer 201 may have a U-shaped cross-sectional profile. In other words, the word line dielectric layer 201 may be inwardly formed in the active area. In some embodiments, the word line dielectric layer 201 may be formed by a thermal oxidation process. For example, the word line dielectric layer 201 may be formed by oxidizing the inner surface of the word line trench TR. In some embodiments, the word line dielectric layer 201 may be formed by a deposition process such as a chemical vapor deposition or an atomic layer deposition. The word line dielectric layer 201 may include a high-k dielectric material, an oxide, a nitride, an oxynitride or combinations thereof. In some embodiments, after a liner polysilicon layer (not shown for clarity) is deposited, the word line dielectric layer 201 may be formed by radical oxidizing the liner polysilicon layer. In some embodiments, after a liner silicon nitride layer (not shown for clarity) is formed, the word line dielectric layer 201 may be formed by radical oxidizing the liner silicon nitride layer.

In some embodiments, the high-k dielectric material may include a hafnium-containing material. The hafnium-containing material may be, for example, hafnium oxide, hafnium silicon oxide, hafnium silicon oxynitride, or a combination thereof. In some embodiments, the high-k dielectric material may be, for example, lanthanum oxide, lanthanum aluminum oxide, zirconium oxide, zirconium silicon oxide, zirconium silicon oxynitride, aluminum oxide or a combination thereof.

With reference to FIG. 2, the word line conductive layer 203 may be formed on the word line dielectric layer 201 and within the word line trench TR. In some embodiments, in order to form the word line conductive layer 203, a conductive layer (not shown for clarity) may be formed to fill the word line trench TR, and a recessing process may be subsequently performed. The recessing process may be performed as an etching back process or sequentially performed as the planarization process and an etching back process. The word line conductive layer 203 may have a recessed shape that partially fills the word line trench TR. That is, the top surface of the word line conductive layer 203 may be lower than the top surface of the substrate 101.

In some embodiments, the word line conductive layer 203 may include a metal, a metal nitride, or a combination thereof. For example, the word line conductive layer 203 may be formed of titanium nitride, tungsten, or a titanium nitride/tungsten. After the titanium nitride is conformally formed, the titanium nitride/tungsten may have a structure where the word line trench TR is partially filled using tungsten. The titanium nitride or the tungsten may be solely used for the word line conductive layer 203. In some embodiments, the word line conductive layer 203 may be formed of, for example, a conductive material such as doped polycrystalline silicon, doped polycrystalline silicon germanium, or a combination thereof. In some embodiments, the word line conductive layer 203 may be formed of, for example, tungsten, aluminum, titanium, copper, the like, or a combination thereof.

With reference to FIG. 2, a dielectric material (not shown) may be deposited by, for example, chemical vapor deposition, to completely fill the word line trenches TR and covering the bottom dielectric layer 105. A planarization process, such as chemical mechanical polishing, may be performed until the top surface 105TS of the bottom dielectric layer 105 is exposed to provide a substantially flat surface for subsequent processing steps and form the word line capping layer 205. In some embodiments, the word line capping layer 205 may be formed of, for example, silicon nitride, or other applicable dielectric material.

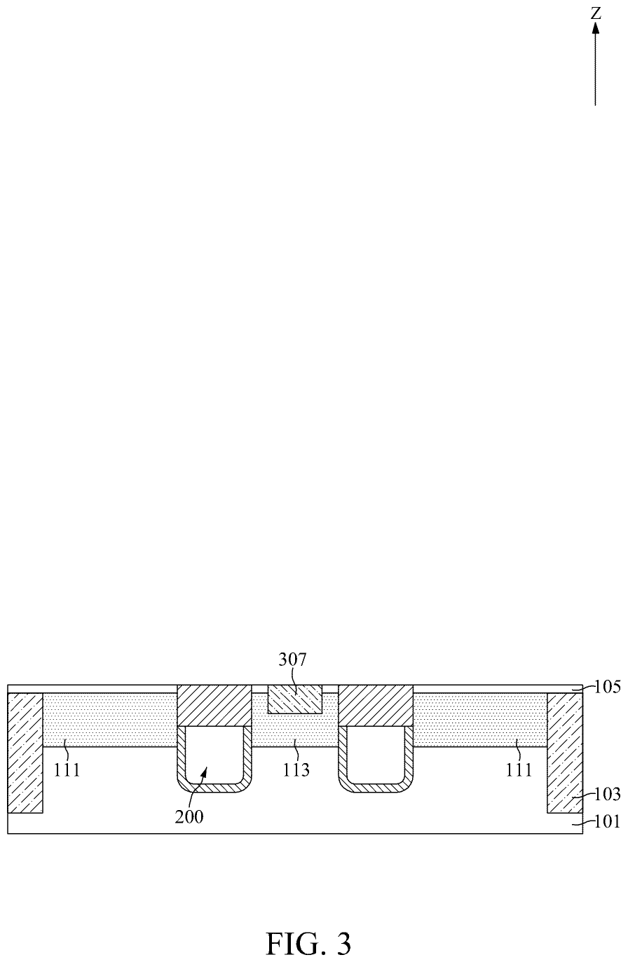

With reference to FIG. 3, a bit line contact 307 may be formed penetrating the bottom dielectric layer 105 and extending to the common source region 113. In some embodiments, the bit line contact 307 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

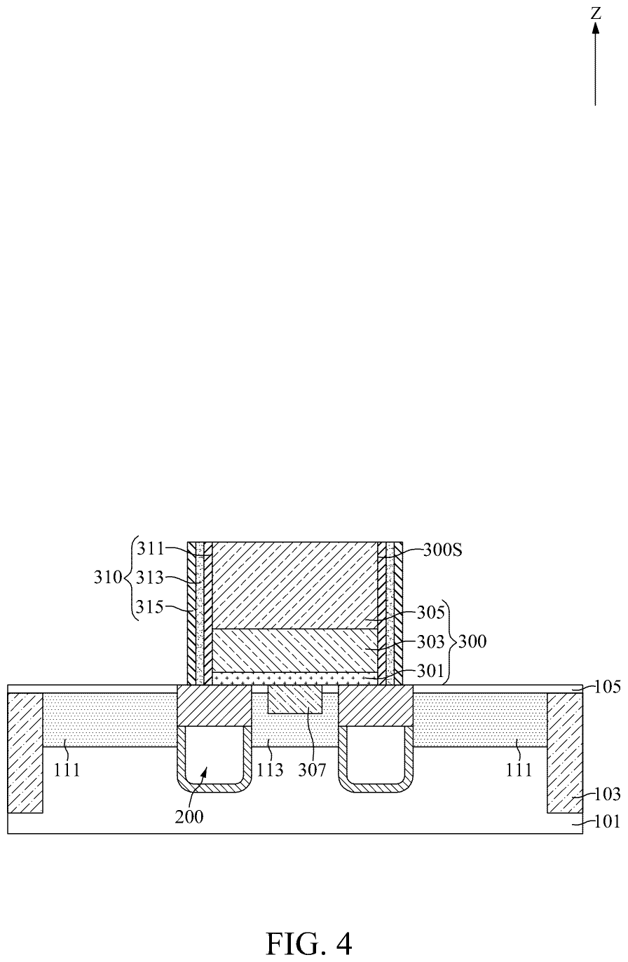

With reference to FIG. 4, the bit line structure 300 may be formed on the bottom dielectric layer 105 and electrically connected to the bit line contact 307. The bit line structure 300 may include a bit line bottom conductive layer 301, a bit line upper conductive layer 303, and a bit line capping layer 305.

The bit line bottom conductive layer 301 may be formed on the bit line contact 307. In some embodiments, the bit line bottom conductive layer 301 may be formed of, for example, doped polycrystalline silicon, doped polycrystalline germanium, doped polycrystalline silicon germanium, or a combination thereof. In some embodiments, the dopants for the bit line bottom conductive layer 301 may include boron, aluminum, gallium, indium, antimony, arsenic, or phosphorus.

The bit line upper conductive layer 303 may be formed on the bit line bottom conductive layer 301. In some embodiments, the bit line upper conductive layer 303 may be formed of, for example, titanium, nickel, platinum, tantalum, cobalt, silver, copper, aluminum, other applicable conductive material, or a combination thereof.

The bit line capping layer 305 may be formed on the bit line upper conductive layer 303. In some embodiments, the bit line capping layer 305 may be formed of, for example, silicon nitride or other applicable insulating material.

With reference to FIG. 4, a plurality of inner spacers 311 may be formed on the sides 300S of the bit line structure 300. In some embodiments, the plurality of inner spacers 311 may be formed of the same material as the bit line capping layer 305. In some embodiments, the plurality of inner spacers 311 may be formed of, for example, silicon nitride or other applicable insulating material. In some embodiments, the plurality of inner spacers 311 may be formed by conformally depositing a layer of insulating material (not shown) over the bottom dielectric layer 105 and a subsequent anisotropic etching process.

With reference to FIG. 4, a plurality of middle spacers 313 may be conformally formed on the plurality of inner spacers 311. In some embodiments, the plurality of middle spacers 313 may be formed of, for example, silicon oxide or other applicable insulating oxides. In some embodiments, the plurality of middle spacers 313 may be formed by conformally depositing a layer of insulating oxide (not shown) over the bottom dielectric layer 105 and a subsequent anisotropic etching process.

With reference to FIG. 4, a plurality of outer spacers 315 may be conformally formed on the plurality of middle spacers 313. In some embodiments, the plurality of outer spacers 315 may be formed of the same material as the plurality of inner spacers 311 or the bit line capping layer 305. In some embodiments, the plurality of outer spacers 315 may be formed of, for example, silicon nitride or other applicable insulating material. In some embodiments, the plurality of outer spacers 315 may be formed by conformally depositing a layer of insulating material (not shown) over the bottom dielectric layer 105 and a subsequent anisotropic etching process.

In some embodiments, the plurality of inner spacers 311 may be optional. That is, the plurality of middle spacers 313 may be directly formed on the side 300S of the bit line structure 300.

With reference to FIGS. 1, 5, and 6, at step S13, a plurality of cell contact structures 400 may be formed on the plurality of drain regions 111, a top inter-dielectric layer 109 may be formed over the plurality of cell contact structures 400, and a plurality of openings OP1 may be formed penetrating the top inter-dielectric layer 109 to expose the plurality of cell contact structures 400.

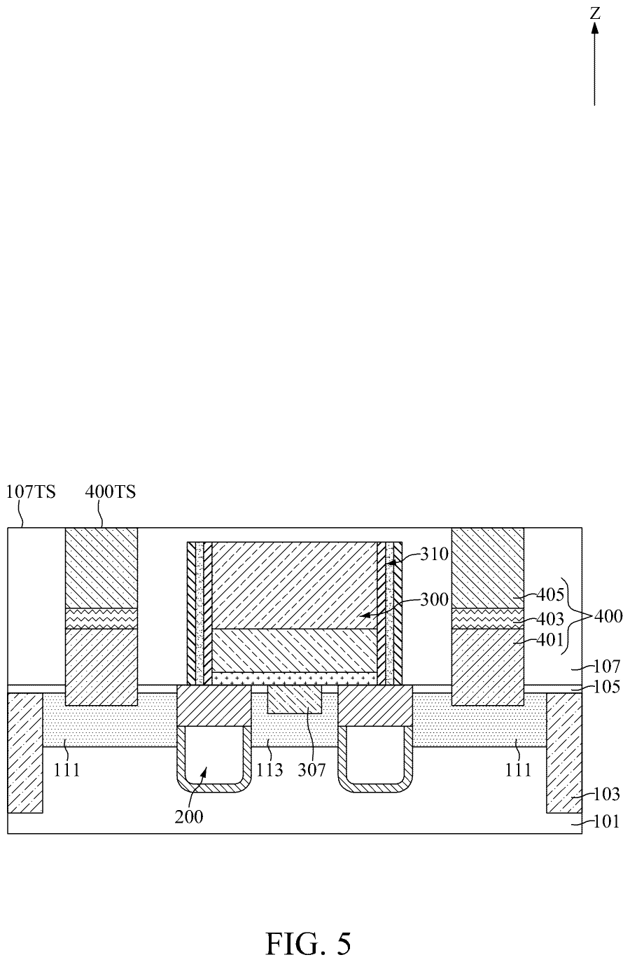

With reference to FIG. 5, a bottom inter-dielectric layer 107 may be formed on the bottom dielectric layer 105 to cover the bit line structure 300, the plurality of inner spacers 311, the plurality of middle spacers 313, and the plurality of outer spacers 315. In some embodiments, the bottom inter-dielectric layer 107 may be formed of, for example, silicon oxide, borophosphosilicate glass, undoped silicate glass, fluorinated silicate glass, low-k dielectric materials, the like, or a combination thereof. The low-k dielectric materials may have a dielectric constant less than 3.0 or even less than 2.5. In some embodiments, the undoped silicate glass can be expressed as formula SiOₓ. The x may be between 1.4 and 2.1. A planarization process, such as chemical mechanical polishing, may be performed to remove excess material and provide a substantially flat surface for subsequent processing steps.

For brevity, clarity, and convenience of description, only one cell contact structure 400 is described.

With reference to FIG. 5, the cell contact structure 400 may penetrate the bottom inter-dielectric layer 107 and the top inter-dielectric layer 109, and extend to the drain region 111. The cell contact structure 400 may connect electrically to the drain region 111. In some embodiments, the cell contact structure 400 may include a cell contact bottom conductive layer 401, a cell contact middle conductive layer 403, and a cell contact top conductive layer 405.

In some embodiments, the cell contact bottom conductive layer 401 may be formed on the drain region 111 or partially immersed in the drain region 111. In some embodiments, the cell contact bottom conductive layer 401 may be formed of, for example, doped polycrystalline silicon, doped polycrystalline germanium, or doped polycrystalline silicon germanium. In some embodiments, the cell contact bottom conductive layer 401 may include p-type dopants or n-type dopants. In some embodiments, the cell contact bottom conductive layer 401 may be formed by, for example, atomic layer deposition, chemical vapor deposition, or other applicable deposition processes. By employing doped polycrystalline silicon, doped polycrystalline germanium, or doped polycrystalline silicon germanium for the cell contact, the junction leakage may be reduced. As a result, the performance of the semiconductor device 1A may be improved.

In some embodiments, the cell contact middle conductive layer 403 may be formed on the cell contact bottom conductive layer 401. In some embodiments, the cell contact middle conductive layer 403 may be formed of, for example, titanium silicide, nickel silicide, nickel platinum silicide, tantalum silicide, or cobalt silicide.

In some embodiments, the cell contact top conductive layer 405 may be formed on the cell contact middle conductive layer 403. In some embodiments, the cell contact top conductive layer 405 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the top surface 400TS of the cell contact structure 400 (i.e., the top surface of the cell contact top conductive layer 405) and the top surface 107TS of the bottom inter-dielectric layer 107 may be substantially coplanar.

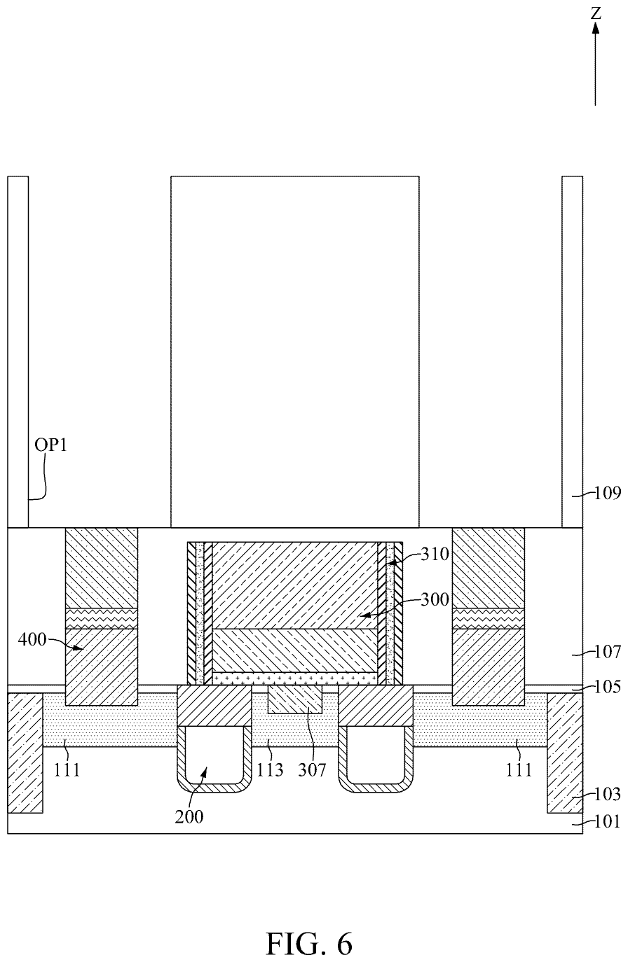

With reference to FIG. 6, a top inter-dielectric layer 109 may be formed on the bottom inter-dielectric layer 107. In some embodiments, the top inter-dielectric layer 109 may be formed of, for example, silicon oxide, borophosphosilicate glass, undoped silicate glass, fluorinated silicate glass, low-k dielectric materials, the like, or a combination thereof. The low-k dielectric materials may have a dielectric constant less than 3.0 or even less than 2.5. In some embodiments, the top inter-dielectric layer 109 may be formed by, for example, chemical vapor deposition or other applicable deposition processes. The plurality of openings OP1 may be formed by a photolithography process and a subsequent etching process. The plurality of cell contact structures 400 may be exposed through the plurality of openings OP1, respectively and correspondingly.

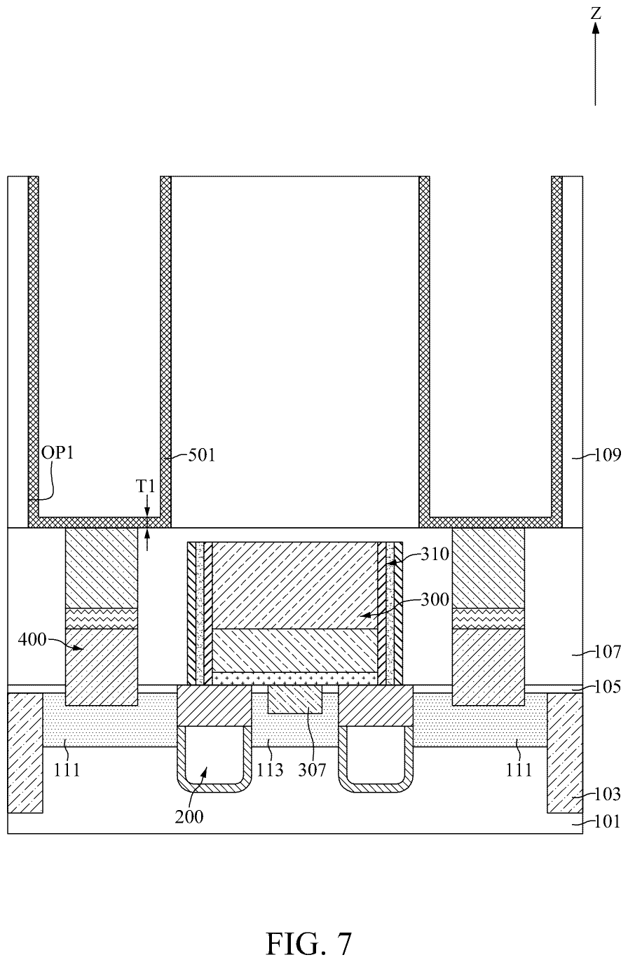

With reference to FIGS. 1 and 7, at step S15, a plurality of bottom electrode layers 501 may be formed within the plurality of openings OP1.

With reference to FIG. 7, the plurality of bottom electrode layers 501 may be formed in the plurality of openings OP1, respectively and correspondingly. For brevity, clarity, and convenience of description, only one bottom electrode layer 501 is described. In some embodiments, the bottom electrode layer 501 may include, for example, titanium nitride, titanium silicon nitride, or a combination thereof. In some embodiments, the bottom electrode layer 501 may be a multi-layered structure such as a bottom layer including titanium nitride and a top layer including titanium silicon nitride.

In some embodiments, the bottom electrode layer 501 may have a low resistivity and an excellent barrier property, and is stable under heat. In some embodiments, the resistivity of the bottom electrode layer 501 may be between about 500 μΩ·cm and about 5000 μΩ·cm. In some embodiments, the titanium content in the bottom electrode layer 501 may be about 10 to 40 atomic percent. The silicon content in the bottom electrode layer 501 may be about 10 to 40 atomic percent. The nitrogen content in the bottom electrode layer 501 may be about 25 to 47 atomic percent. In some embodiments, the thickness T1 of the bottom electrode layer 501 may be between about 60 angstroms and about 120 angstroms.

In some embodiments, the bottom electrode layer 501 may be formed by a thermal chemical vapor deposition process. During the thermal chemical vapor deposition process, a titanium-containing gas, a silicon-containing gas, and a nitrogen-containing gas may be introduced over the top inter-dielectric layer 109 to form the bottom electrode layer 501. The titanium-containing gas may be, for example, tetraxydimethylaminotitanium or tetraxydiethylaminotitanium. The silicon-containing gas may be, for example, SiH₂Cl₂, SiHCl₃, SiCl₄, SiH₄, or Si₂H₆. The nitrogen-containing gas may be, for example, ammonia or monomethylhydrazine. The flow rate of the titanium-containing gas may be between about 5 standard cubic centimeters per minute (sccm) and about 50 sccm. The flow rate of the silicon-containing gas may be between about 5 sccm and about 500 sccm. The flow rate of the nitrogen-containing gas may be between about 50 sccm and about 500 sccm. The process pressure of the thermal chemical vapor deposition process may be between about 0.3 Torr and about 5 Torr. The process temperature may be between about 400° C. and about 650° C.

Alternatively, in some embodiments, the bottom electrode layer 501 may be formed by a plasma chemical vapor deposition process. The gas for generating plasma may be, for example, hydrogen and argon. The frequency of radio-frequency power of the plasma may be 13.56 MHz. The radio-frequency power of the plasma may be between about 200 W and about 800 W. The flow rate of the titanium-containing gas (e.g., TiCl₄) may be between about 1 sccm and about 10 sccm. The flow rate of the silicon-containing gas (e.g., SiH₄) may be between about 0.1 sccm and about 10 sccm. The flow rate of the nitrogen-containing gas (e.g., N₂) may be between about 30 sccm and about 500 sccm. The flow rate of hydrogen may be between about 100 and 3000 sccm. The flow rate of argon may be between about 100 and 2000 sccm. The process pressure of the plasma chemical vapor deposition process may be between about 0.5 Torr and about 5 Torr. The process temperature may be between about 350° C. and about 450° C.

Alternatively, in some embodiments, a layer of titanium nitride and a layer of silicon nitride may be sequentially formed within the opening OP1. An annealing process may be performed to turn the layer of titanium nitride and the layer of silicon nitride into the bottom electrode layer 501.

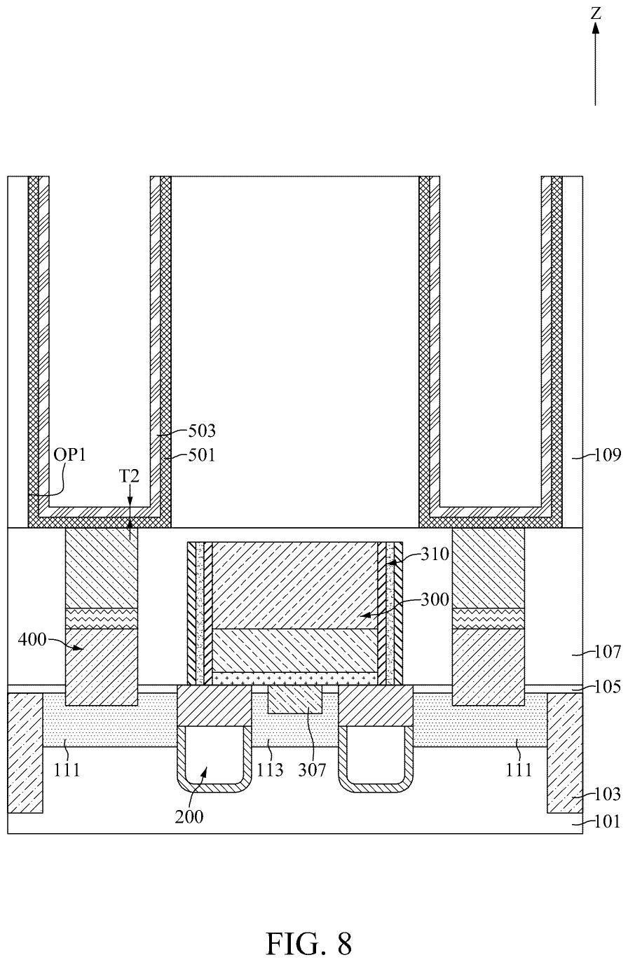

With reference to FIGS. 1 and 8, at step S17, a plurality of interface layers 503 may be formed on the plurality of bottom electrode layers 501 and within the plurality of openings OP1.

With reference to FIG. 8, a plurality of interface layers 503 may be formed on the plurality of bottom electrode layers 501, respectively and correspondingly. In some embodiments, the plurality of interface layers 503 may include, for example, titanium oxide (TiOₓ). In some embodiments, the thickness T2 of the interface layer 503 may be between about 40 angstroms and about 80 angstroms.

In some embodiments, the interface layers 503 may be formed by performing oxygen treatment on the bottom electrode layers 501. This oxygen treatment may involve applying ozone to the bottom electrode layer 501 to form the interface layer 503. The process temperature for the oxygen treatment may range from about 230° C. to about 280° C. During the oxygen treatment, oxygen vacancies in the bottom electrode layer 501 may be filled (eliminated), effectively reducing leakage caused by these vacancies.

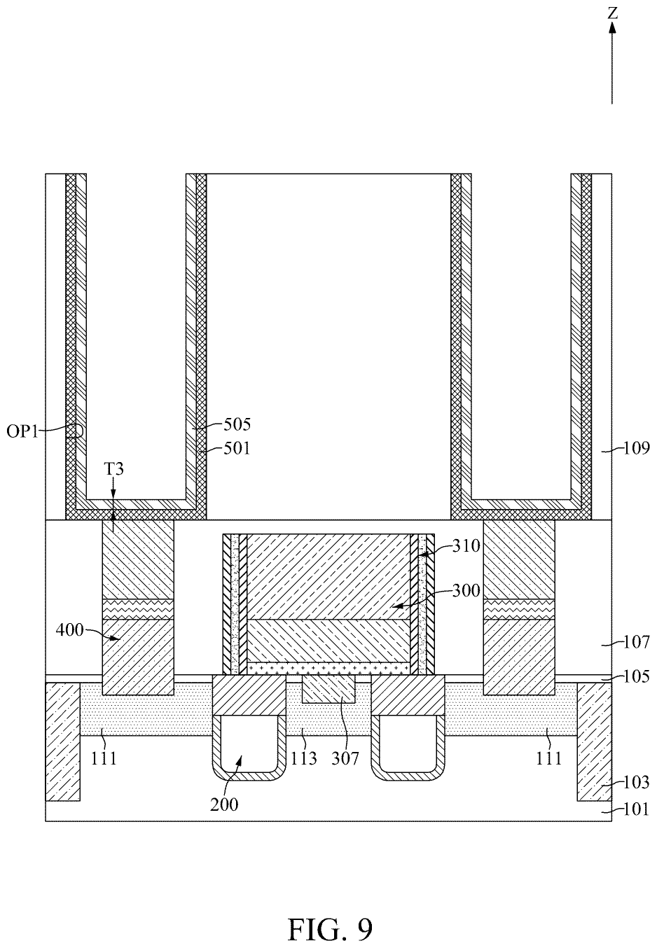

With reference to FIGS. 1 and 9, at step S19, a nitrogen treatment may be performed to turn the plurality of interface layers 503 into a plurality of treated interface layers 505.

For brevity, clarity, and convenience of description, only one treated interface layer 505 is described.

With reference to FIG. 9, the treated interface layer 505 may be formed on the bottom electrode layers 501 and within the opening OP1. In some embodiments, the thickness T3 of the treated interface layer 505 may be between about 40 angstroms and about 80 angstroms. In some embodiments, the treated interface layer 505 may include titanium oxide nitride (TiON).

In some embodiments, the nitrogen treatment may be, for example, a nitridation process such as a plasma nitridation process. The plasma nitridation process may increase the nitrogen content of the interface layer 503 so as to form the treated interface layer 505. It may utilize plasma sources to generate high-density plasma and reactive species for substrate treatment. The general process may include positioning the intermediate semiconductor device in a processing chamber; introducing process gas into the plasma source; generating plasma within the plasma source; and treating the intermediate semiconductor device with the reactive species (e.g., radicals) from the plasma.

Detailedly, the intermediate semiconductor device illustrated in FIG. 8 may be positioned on a substrate support in a processing region/volume of the processing chamber of the nitridation process.

In some embodiments, the processing chamber can have a plasma processing source that is integrated within and/or positioned above the processing chamber (or positioned above the processing region/volume of the processing chamber). The plasma processing source may include an inductively coupled plasma source that can be operated at desired power levels which will be illustrated below.

Next, a process gas, which includes a nitrogen-containing source and a carrier gas, may be introduced into the plasma processing source. In some embodiments, the nitrogen-containing source may be ammonia (NH₃), nitrogen (N₂), hydrazine (N₂H₄), or a combination thereof, and the carrier gas may include noble gases like helium (He), argon (Ar), neon (Ne), krypton (Kr), xenon (Xe), or a combination thereof. In some embodiments, the flow rate of the nitrogen-containing source may range from about 50 sccm to about 5,000 sccm, for example, from 100 sccm to about 700 sccm, from 150 sccm to 650 sccm, from 200 sccm to 600 sccm, from 250 sccm to 550 sccm, from 300 sccm to 500 sccm, or from 350 sccm to 450 sccm.

In some embodiments, the flow rate of the carrier gas may range from about 1,000 sccm to 20,000 sccm, for example, from 1,500 sccm to 4,500 sccm, from 2,000 sccm to 4,000 sccm, from 2,500 sccm to 3,500 sccm, from 2,500 sccm to 3,000 sccm, or from 3,000 sccm to 3,500 sccm.

In some embodiments, the flow rate of the nitrogen-containing source may range from about 1% to about 25% of the carrier gas flow rate, such as from about 2% to about 22%, from about 3% to about 20%, from about 5% to about 15%, from about 8% to about 12%, from about 5% to about 10%, or from about 10% to about 15%. Alternatively, in some embodiments, the flow rate of the nitrogen-containing source may range from about 3% to about 100% of the carrier gas flow rate, such as from about 3% to about 20% or from about 5% to about 15%.

Subsequently, plasma may be generated by applying radio frequency (RF) power, typically from about 1 kW to about 12 kW (e.g., from about 2 kW to about 10 kW, from about 3 kW to about 9 kW, from about 4 kW to about 8 kW, or from about 5 kW to about 7 kW), to the plasma source. This process forms radical species, such as nitrogen radicals (N*), hydrogen radicals (H*), NH₂*, or NH*, from the process gas. In other words, this process may form radicals including nitrogen and/or hydrogen.

Next, the radicals and neutral particles may flow towards the intermediate semiconductor device in the processing chamber. In some embodiments, the radicals and neutral particles may flow through a separation grid towards the intermediate semiconductor device.

In some embodiments, the intermediate semiconductor device may be processed at a controlled temperature, which may range from about 100° C. to about 1,200° C. (e.g., from about 150° C. to about 650° C., from about 200° C. to about 600° C., from about 250° C. to about 550° C., from about 300° C. to about 500° C., from about 350° C. to about 450° C., from about 350° C. to about 400° C., or from about 400° C. to about 450° C.), and a pressure ranging from about 25 mTorr to about 5 Torr (e.g., from about 50 mTorr to about 2 Torr, from about 100 mTorr to about 1.25 Torr, from about 200 mTorr to 1 about Torr, from about 300 mTorr to about 900 mTorr, from about 400 mTorr to about 800 mTorr, from about 500 mTorr to about 700 mTorr, from about 500 mTorr to about 600 mTorr, or from about 600 mTorr to about 700 mTorr).

In some embodiments, the processing time of the nitridation process may range from about 5 seconds to about 10 minutes, such as from about 15 seconds to about 10 minutes, from about 30 seconds to about 5 minutes, from about 1 minute to about 4 minutes, or from about 2 minutes to about 3 minutes.

In some embodiments, the heat source to maintain the process temperature may include lamps positioned above or below the intermediate semiconductor device, a heater embedded within the substrate support, or combinations thereof.

In some embodiments, the nitrogen dose (i.e., a number of nitrogen atoms per unit area) of the treated interface layer 505 may be controlled to be between about 5×10\hat{ }15 atoms/cm\hat{φ}2 and about 50×10\hat{ }15 atoms/cm\hat{ }2, such as between about 10×10\hat{ }15 atoms/cm\hat{φ}2 and about 40×10\hat{ }15 atoms/cm\hat{ }2, between about 15×10\hat{ }15 atoms/cm\hat{ }2 and about 35×10\hat{ }15 atoms/cm\hat{ }2, or between about 20×10\hat{ }15 atoms/cm\hat{ }2 and about 30×10\hat{ }15 atoms/cm\hat{ }2; another possible range may be between about 10×10\hat{ }15 atoms/cm\hat{ }2 and about 25×10\hat{ }15 atoms/cm\hat{ }2, between about 12×10\hat{ }15 atoms/cm\hat{ }2 and about 20×10\hat{ }15 atoms/cm\hat{ }2, or between about 14×10\hat{ }15 atoms/cm\hat{ }2 and about 18×10\hat{ }15 atoms/cm\hat{ }2.

In some embodiments, the change in nitrogen dose (i.e., the nitrogen dose of the interface layer 503 and the nitrogen dose of the treated interface layer 505) may range from about 1×10\hat{ }15 atoms/cm\hat{ }2 to about 50×10\hat{ }15 atoms/cm\hat{ }2, from about 5×10\hat{ }15 atoms/cm\hat{ }2 to about 45×10\hat{ }15 atoms/cm\hat{ }2, from about 10×10\hat{ }15 atoms/cm\hat{ }2 to about 40×10\hat{ }15 atoms/cm\hat{ }2, from about 15×10\hat{ }15 atoms/cm\hat{ }2 to about 35×10\hat{ }15 atoms/cm\hat{ }2, or from about 20×10\hat{ }15 atoms/cm\hat{ }2 to about 30×10\hat{ }15 atoms/cm\hat{ }2; another possible range may be from about 1×10\hat{φ}15 atoms/cm\hat{ }2 to about 30×10\hat{ }15 atoms/cm\hat{ }2, from about 10×10\hat{ }15 atoms/cm\hat{ }2 to about 25×10\hat{ }15 atoms/cm\hat{ }2, from about 12×10\hat{ }15 atoms/cm\hat{ }2 to about 20×10\hat{ }15 atoms/cm\hat{ }2, or from about 14×10\hat{ }15 atoms/cm\hat{ }2 to about 18×10\hat{ }15 atoms/cm\hat{ }2.

In some embodiments, the nitrogen content (in units of atomic percent) of the treated interface layer 505 may range from about 1% to about 45% or less, such as from about 3% to about 40%, from about 5% to about 35%, from about 10% to about 30%, or from about 15% to about 25% or from about 10% to about 20%.

In some embodiments, the change in nitrogen content may be from about 1% or more up to about 500% or more, such as from about 50% to about 400%, from about 75% to about 200%, or from about 100% to about 150%. For example, the nitrogen content may increase by about 1% or more and/or about 50% or less, such as from about 5% to about 45%, from about 10% to about 40%, from about 15% to about 35%, or from about 20% to about 30%. The nitrogen content can be measured by x-ray photoelectron spectroscopy.

In some embodiments, during the nitridation process, hydrogen may be co-flowed with the nitrogen-containing source.

In some embodiments, a cleaning process may be performed before, during, or after the nitridation process. Wet chemistry methods, such as diluted HF, ammonium hydroxide/peroxide, sulfuric acid/peroxide, or their combinations can be used, or the cleaning process can be performed using plasma-generated species like hydrogen radicals and/or oxygen radicals. The cleaning process can be performed in the same or different processing chambers and can be performed cyclically.

The nitrogen treatment using plasma nitridation may provide higher nitrogen doping and nitride thickness with lower thermal budgets. It may also offer high conformality. Furthermore, the nitrogen radicals generated during the nitrogen treatment may fill the vacancies of the bottom electrode layer 501 to reduce the leakage of the bottom electrode layer 501. The hydrogen radicals generated during the nitrogen treatment may react with carbon or chlorine within the bottom electrode layer 501 to lower the impurity of the bottom electrode layer 501.

With reference to FIG. 1 and FIGS. 10 to 12, at step S21, a capacitor bottom dielectric layer 507 may be conformally formed on the plurality of treated interface layers 505, a capacitor top dielectric layer 509 may be conformally formed on the capacitor bottom dielectric layer 507, and a top electrode layer 511 may be formed on the capacitor top dielectric layer 509 to configure a plurality of capacitor structures 500.

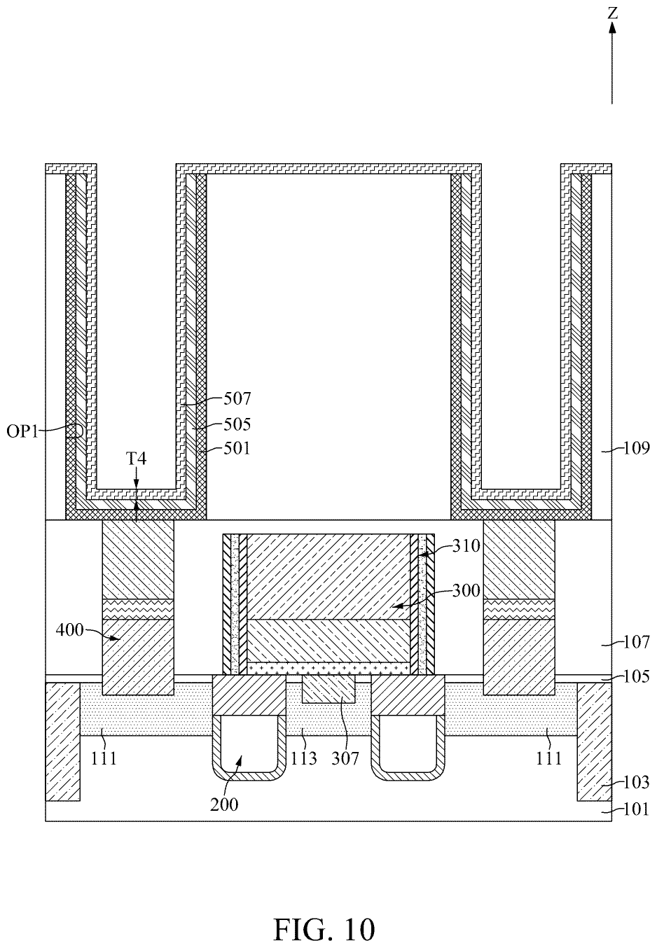

With reference to FIG. 10, the capacitor bottom dielectric layer 507 may be conformally formed on the plurality of treated interface layers 505 and on the top surface 109TS of the top inter-dielectric layer 109. In some embodiments, the capacitor bottom dielectric layer 507 may include silicon oxide (e.g., SiO₂), a dielectric material with high dielectric constant (high-k dielectric material), such as zirconium oxide (e.g., ZrO₂), hafnium oxide (e.g., HfO₂), titanium oxide (e.g., TiO₂), aluminum oxide (e.g., AlO), or a combination thereof. In some embodiments, the capacitor bottom dielectric layer 507 may be formed by a conformal deposition process, such as a chemical vapor deposition process or an atomic layer deposition process. In some embodiments, the thickness T4 of the capacitor bottom dielectric layer 507 may be between about 5 angstroms and about 30 angstroms.

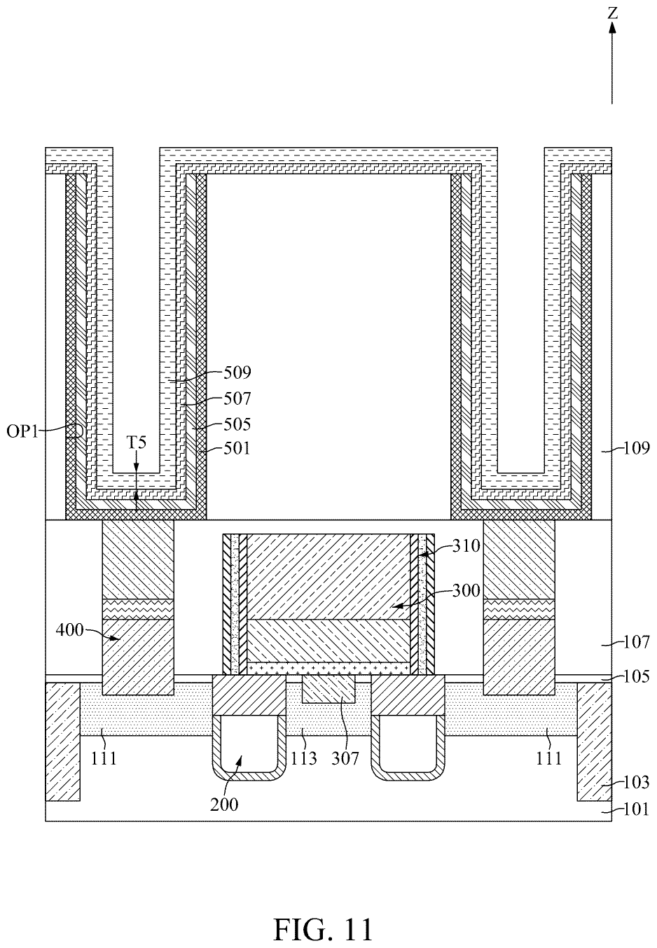

With reference to FIG. 11, the capacitor top dielectric layer 509 may be conformally formed on the capacitor bottom dielectric layer 507. In some embodiments, the capacitor top dielectric layer 509 may include a single layer or multiple layers. In some embodiments, the dielectric layer 112 may include silicon oxide, a high-k dielectric material, or a combination thereof. For example, the capacitor top dielectric layer 509 may be a tri-layer structure including a layer of zirconium oxide sandwiched by a layer of hafnium oxide and a layer of aluminum oxide. In some embodiments, the capacitor top dielectric layer 509 may be formed by a conformal deposition process, such as a chemical vapor deposition process or an atomic layer deposition process. In some embodiments, the thickness T5 of the capacitor top dielectric layer 509 may be between about 4.0 nm and about 8.0 nm or between about 4.0 nm and about 7.0 nm. In some embodiments, the capacitor top dielectric layer 509 may be doped with aluminum. The aluminum content (in units of atomic percent) of the capacitor top dielectric layer 509 may be between about 1% and about 8%.

In some embodiments, the high-k dielectric material may include a hafnium-containing material. The hafnium-containing material may be, for example, hafnium oxide, hafnium silicon oxide, hafnium silicon oxynitride, or a combination thereof. In some embodiments, the high-k dielectric material may be, for example, lanthanum oxide, lanthanum aluminum oxide, zirconium oxide, zirconium silicon oxide, zirconium silicon oxynitride, aluminum oxide or a combination thereof.

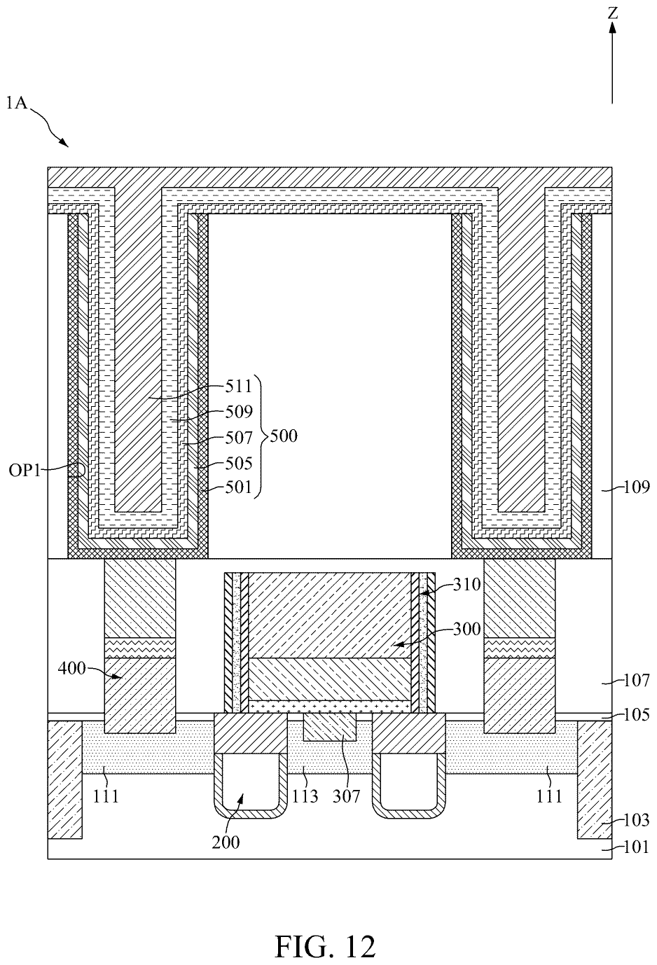

With reference to FIG. 12, the top electrode layer 511 may be formed on the capacitor top dielectric layer 509 and completely fill the plurality of openings OP1. In some embodiments, the top electrode layer 511 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the top electrode layer 511 may include titanium nitride, titanium silicon nitride, or a combination thereof. In some embodiments, the top electrode layer 511 may be formed by, for example, chemical vapor deposition, physical vapor deposition, sputtering, electroplating, electroless plating, atomic layer deposition, or other applicable deposition processes.

A planarization process, such as chemical mechanical polishing, may be performed to remove excess material and provide a substantially flat surface for subsequent processing steps.

The plurality of bottom electrode layers 501, the plurality of treated interface layers 505, the capacitor bottom dielectric layer 507, the capacitor top dielectric layer 509, and the top electrode layer 511 together configure the plurality of capacitor structures 500.

Using the interface layer 503 formed through oxygen treatment can reduce the leakage of the capacitor structures 500 by eliminating (or filling) oxygen vacancies during the treatment process. Additionally, the treated interface layer 505, formed through nitrogen treatment and composed of titanium oxide nitride, can minimize impurities in the bottom electrode layer 501. These improvements collectively enhance the performance and reliability of the semiconductor device 1A.

Experimental results further demonstrate that combining the treated interface layer 505, which includes titanium oxide nitride, with the capacitor bottom dielectric layer 507, composed solely of hafnium oxide, effectively reduces leakage in the capacitor structures 500 without compromising their capacitance. This combination provides a balanced solution for improving both the electrical and functional properties of the capacitor structures.

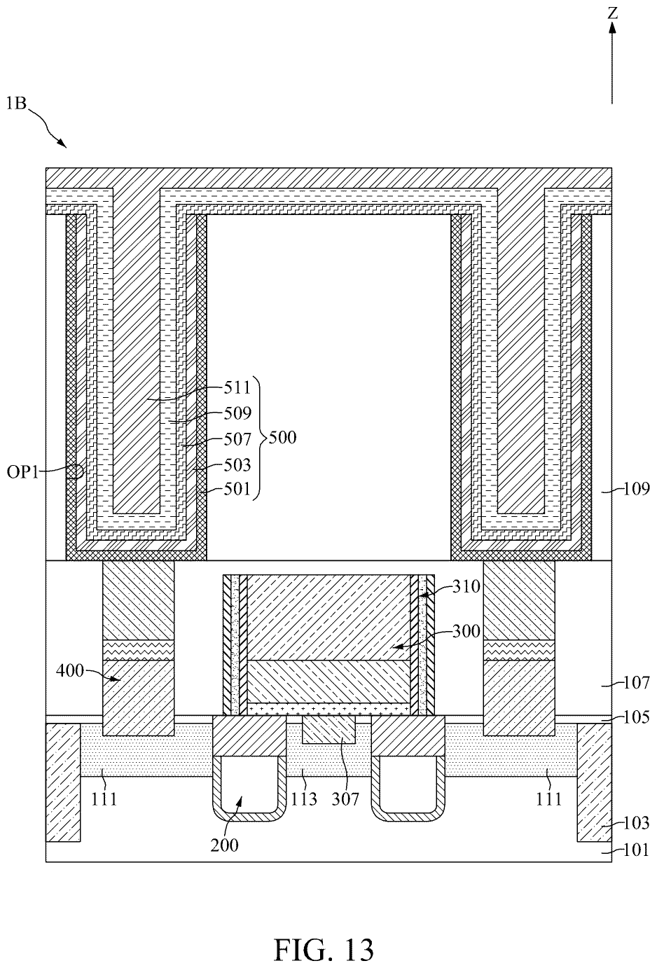

FIG. 13 illustrates, in a schematic cross-sectional view diagram, a semiconductor device 1B in accordance with another embodiment of the present disclosure.

With reference to FIG. 13, the semiconductor device 1B may have a structure similar to that illustrated in FIG. 12. The same or similar elements in FIG. 13 as in FIG. 12 have been marked with similar reference numbers and duplicative descriptions have been omitted.

For the semiconductor device 1B, the nitrogen treatment may be omitted. The capacitor bottom dielectric layer 507 may be conformally formed on the plurality of interface layers 503. The plurality of bottom electrode layers 501, the plurality of interface layers 503, the capacitor bottom dielectric layer 507, the capacitor top dielectric layer 509, and the top electrode layer 511 together configure the plurality of capacitor structures 500.

One aspect of the present disclosure provides a semiconductor device including a substrate; a capacitor structure including a bottom electrode layer positioned above the substrate, a treated interface layer positioned on the bottom electrode layer, a capacitor bottom dielectric layer positioned on the treated interface layer, a capacitor top dielectric layer positioned on the capacitor bottom dielectric layer, and a top electrode layer positioned on the capacitor top dielectric layer. The treated interface layer includes titanium oxide nitride.

Another aspect of the present disclosure provides a semiconductor device including a substrate; a capacitor structure including a bottom electrode layer positioned above the substrate, an interface layer positioned on the bottom electrode layer, a capacitor bottom dielectric layer positioned on the interface layer, a capacitor top dielectric layer positioned on the capacitor bottom dielectric layer, and a top electrode layer positioned on the capacitor top dielectric layer. The interface layer includes titanium oxide.

Another aspect of the present disclosure provides a method for fabricating a semiconductor device including providing a substrate; forming a top inter-dielectric layer above the substrate; forming an opening penetrating the top inter-dielectric layer; forming a bottom electrode layer within the opening; performing an oxygen treatment to form an interface layer on the bottom electrode layer; performing a nitrogen treatment to turn the interface layer into a treated interface layer; forming a capacitor bottom dielectric layer on the treated interface layer; forming a capacitor top dielectric layer on the capacitor bottom dielectric layer; and forming a top electrode layer on the capacitor top dielectric layer. The treated interface layer includes titanium oxide nitride. The bottom electrode layer, the treated interface layer, the capacitor bottom dielectric layer, the capacitor top dielectric layer, and the top electrode layer configure a capacitor structure.

Due to the design of the semiconductor device of the present disclosure, the leakage of the capacitor structures 500 may be reduced by using the interface layer 503 formed through oxygen treatment. Additionally, the treated interface layer 505, formed through nitrogen treatment and composed of titanium oxide nitride, can minimize impurities in the bottom electrode layer 501. These improvements collectively enhance the performance and reliability of the semiconductor device 1A. Furthermore, experimental results further demonstrate that combining the treated interface layer 505, which includes titanium oxide nitride, with the capacitor bottom dielectric layer 507, composed solely of hafnium oxide, effectively reduces leakage in the capacitor structures 500 without compromising their capacitance. This combination provides a balanced solution for improving both the electrical and functional properties of the capacitor structures.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of the ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate; and
a capacitor structure, comprising:
a bottom electrode layer positioned above the substrate;
an interface layer positioned on the bottom electrode layer;
a capacitor bottom dielectric layer positioned on the interface layer;
a capacitor top dielectric layer positioned on the capacitor bottom dielectric layer; and
a top electrode layer positioned on the capacitor top dielectric layer;
wherein the interface layer comprises titanium oxide.

2. The semiconductor device of claim 1, wherein the capacitor bottom dielectric layer comprises a high-k dielectric material.

3. The semiconductor device of claim 2, wherein the high-k dielectric material is hafnium oxide.

4. The semiconductor device of claim 3, wherein a thickness of the interface layer is between about 40 angstroms and about 80 angstroms.

5. The semiconductor device of claim 3, wherein the bottom electrode layer comprises titanium nitride, titanium silicon nitride, or a combination thereof.

6. The semiconductor device of claim 3, wherein a thickness of the bottom electrode layer is between about 60 angstroms and about 120 angstroms.

7. The semiconductor device of claim 3, wherein a thickness of the capacitor bottom dielectric layer is between about 5 angstroms and about 30 angstroms.

8. The semiconductor device of claim 3, wherein a thickness of the capacitor top dielectric layer is between about 4.0 nm and about 8.0 nm.

9. The semiconductor device of claim 3, wherein the capacitor top dielectric layer comprises hafnium oxide, zirconium oxide, aluminum oxide, or a combination thereof.

10. The semiconductor device of claim 3, wherein an aluminum content of the capacitor top dielectric layer is between about 1% and about 8%.

11. The semiconductor device of claim 3, wherein the top electrode layer comprises titanium nitride, titanium silicon nitride, or a combination thereof.
